(19) United States
(12) Patent Application Publication
(10) Pub. No.: US 2026/0113922 A1
(43) Pub. Date: Apr. 23, 2026

(54) SEMICONDUCTOR DEVICE COMPRISING BACK PATTERN

(71) Applicant: Samsung Electronics Co., Ltd., Suwon-si (KR)

(72) Inventors: Hoyoung Tang, Suwon-si (KR); Tae-Hyung KIM, Suwon-si (KR); Changhoon Do, Suwon-si (KR); Eojin Lee, Suwon-si (KR)

(21) Appl. No.: 19/367,556

(22) Filed: Oct. 23, 2025

(30) Foreign Application Priority Data
Oct. 23, 2024 (KR) 10-2024-0145834
Feb. 20, 2025 (KR) 10-2025-0022533

(51) Int. Cl. H10B 10/00

(52) U.S. Cl. CPC H10B 10/125

(57) ABSTRACT

A semiconductor device includes memory cells on a front surface of a substrate, a first back pattern on a back surface of the substrate, and a second back pattern on the back surface of the substrate. The first back pattern includes first ground lines arranged in a first direction and extending in a second direction intersecting the first direction, and power lines extending in the second direction, where the first ground lines and the power lines are arranged alternately in the first direction, and the second back pattern includes back word lines arranged in the second direction and extending in the first direction.

### CROSS-REFERENCE TO RELATED APPLICATIONS

This application claims priority under 35 U.S.C. § 119 to Korean Patent Application Nos. 10-2024-0145834 filed on Oct. 23, 2024, and 10-2025-0022533 filed on Feb. 20, 2025, in the Korean Intellectual Property Office, the disclosures of which are incorporated by reference herein in their entireties.

### BACKGROUND

As the degree of integration of a semiconductor device is improved, a more complex routing resource may be desired

### SUMMARY

As the design rule of the semiconductor device is gradually shrunk and the complexity of design increases, it is gradually difficult to secure the routing resource within a limited physical space. In addition, as a path of a wire increases, the resistance of the wire may increase, the parasitic capacitance between wires may increase, and the dimensions of the semiconductor device may increase. Accordingly, it may be desired to place the routing resource efficiently.

Implementations of the present disclosure provide a semiconductor device capable of improving an electrical characteristic.

Implementations of the present disclosure provide a semiconductor device capable of improving the stability of a power supply or the stability of a signal transfer.

An aspect of the present disclosure provides a semiconductor device including: a plurality of memory cells on a front surface of a substrate; a first back pattern on a back surface of the substrate; and a second back pattern on the back surface of the substrate. The first back pattern includes a plurality of first ground lines arranged in a first direction and extending in a second direction intersecting the first direction, and a plurality of power lines extending in the second direction. The plurality of first ground lines and the plurality of power lines are arranged alternately in the first direction. The second back pattern includes a plurality of back word lines arranged in the second direction and extending in the first direction.

Another aspect of the present disclosure provides a semiconductor device including: a plurality of memory cells on a front surface of a substrate; a first back pattern on a back surface of the substrate; and a second back pattern on the back surface of the substrate. The first back pattern includes a plurality of first ground lines arranged in a first direction and extending in a second direction intersecting the first direction. The second back pattern includes a plurality of second ground lines arranged in the second direction and extending in the first direction. The plurality of second ground lines are connected to the plurality of first ground lines.

Another aspect of the present disclosure provides a semiconductor device including: a plurality of memory cells on a substrate; a signal back pattern on a back surface of the substrate; a first front pattern on a front surface of the substrate; a second front pattern on a front surface of the first front pattern; and a plurality of first word via lines connecting the signal back pattern and the second front pattern. The signal back pattern includes a plurality of back word lines extending in a first direction and arranged in a second direction intersecting the first direction. The first front pattern includes a plurality of first front word lines arranged in the first direction and extending in the second direction. The second front pattern includes a plurality of second front word lines extending in the first direction and vertically overlapping the plurality of back word lines. The plurality of second front word lines are connected to the plurality of first front word lines. The plurality of first word via lines connect first ends of the plurality of second front word lines and first ends of the plurality of back word lines, and connect second ends of the plurality of second front word lines and second ends of the plurality of the back word lines.

### BRIEF DESCRIPTION OF DRAWINGS

FIG. 1 is a circuit diagram illustrating an example of a semiconductor device.

FIG. 2 is a view illustrating a layout of an example of a semiconductor device.

FIG. 3 is a view illustrating a layout of an example of a semiconductor device.

FIG. 4 is a cross-sectional view taken along line I-I′ of FIG. 2.

FIG. 5 is a cross-sectional view taken along line II-II′ of FIG. 2.

FIG. 6 is a view illustrating a layout of an example of a first back pattern and an example of a second back pattern.

FIG. 7 is a view illustrating a layout of an example of a second back pattern.

FIG. 8 is a view illustrating a layout of an example of a first back pattern, an example of a second back pattern, and an example of a memory cell.

FIG. 9 is a view illustrating a layout of an example of a first back pattern and an example of a second back pattern.

FIG. 10 is a view illustrating an example of a first back pattern, an example of a second back pattern, an example of a memory cell, and an example of a first front pattern.

FIG. 11 is a view illustrating a layout of an example of a first back pattern, an example of a second back pattern, and an example of a memory cell.

FIG. 12 is a view illustrating a layout of an example of a first back pattern, an example of a second back pattern, an example of a memory cell, and an example of a first front pattern.

FIG. 13 is a view illustrating a layout of an example of a first back pattern and an example of a second back pattern.

FIG. 14 is a view illustrating a layout of an example of a first back pattern and an example of a second back pattern.

FIG. 15 is a view illustrating a layout of an example of a first back pattern and an example of a second back pattern.

FIG. 16 is a view illustrating a layout of an example of a first back pattern and an example of a second back pattern.

FIG. 17 is a view illustrating a layout of an example of a first back pattern, an example of a second back pattern, and an example of memory cells.

FIG. 18 is a view illustrating a layout of an example of a first back pattern and an example of a second back pattern.

FIG. 19 is a view illustrating a layout of an example of a first back pattern, an example of a second back pattern, and an example of memory cells.

FIG. 20 is a view illustrating a layout of an example of a first back pattern, an example of a second back pattern, an example of memory cells, and an example of a second front pattern.

### DETAILED DESCRIPTION

Hereinafter, implementations of the present disclosure will be described clearly and in detail with reference to the accompanying drawings.

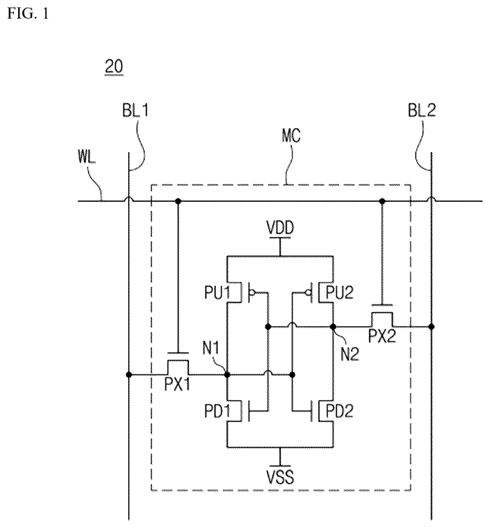

FIG. 1 is a circuit diagram illustrating a semiconductor device according to some implementations. The circuit diagram of FIG. 1 shows an equivalent circuit 20 corresponding to one memory cell MC included in a semiconductor device. In some implementations, the remaining memory cells MC may have the same structure as the memory cell MC illustrated in FIG. 1.

Referring to FIG. 1, the semiconductor device may include a memory cell array including the memory cells MC, a word line connected to the memory cell MC, a first bit line BL1, and a second bit line BL2, and the first and second bit lines BL1 and BL2 may be connected to the memory cell MC. In some implementations, the memory cell array may correspond to an embedded memory device, and the semiconductor device may further include any other components which input data to the memory cell array or output data from the memory cell array. For example, the semiconductor device may further include a row driver, a column driver, and control logic. Unlike the above description, in some implementations, the memory cell array may correspond to a standalone memory device.

The memory cell array may receive a command, an address, and data. For example, the memory cell array may receive a command directing an input, an address, and data, and the received data may be stored in memory cells MC corresponding to the address. In contrast, the memory cell array may receive a command directing an output and an address and may output data from memory cells MC corresponding to the address.

The memory cell array may include the memory cells MC arranged in a plurality of rows and a plurality of columns. That is, the memory cells MC may be arranged in the form of a matrix. The memory cells MC included in the memory cell array may correspond to volatile memory cells MC or nonvolatile memory cells MC. For example, the memory cells MC may include static random access memory (SRAM) cells or dynamic random access memory (DRAM) cells. For example, the memory cells MC may include flash memory cells or resistive random access memory (RRAM) cells. For convenience of description, the memory cell MC according to some implementations will be described based on the SRAM cell, but the technical ideal of the present disclosure is not limited thereto.

The memory cell MC may be connected to a word line WL. In detail, memory cells MC arranged along one row may be connected in common to one word line WL.

The memory cell MC may be connected to the first bit line BL1 and the second bit line BL2. That is, one memory cell MC may be connected to a pair of bit lines BL1 and BL2. One of a pair of bit lines BL1 and BL2 may be referred to as a “bit line BL1”, and the other thereof may be referred to as a “complementary bit line BL2”. The first bit lines BL1 and the second bit lines BL2 may be arranged alternately along memory cells MC arranged in a row direction.

Each of the memory cells MC may include two transistors PX1 and PX2 and a pair of inverters. For example, each of the memory cells MC may include a first pass transistor PX1, a second pass transistor PX2, a first inverter, and a second inverter.

An input terminal of the first inverter and an output terminal of the second inverter may be connected to each other, and an output terminal of the first inverter and an input terminal of the second inverter may be connected to each other. An input and an output of a pair of inverters may be cross-coupled to each other, and the memory cell MC may store data in units of bit. The memory cell MC may be referred to as a “bitcell”.

The first pass transistor PX1 may be connected to the output terminal of the first inverter and the input terminal of the second inverter, and the second pass transistor PX2 may be connected to the output terminal of the second inverter and the input terminal of the first inverter. The first pass transistor PX1 may be referred to as a “first pass gate transistor PX1”, and the second pass transistor PX2 may be referred to as a “second pass gate transistor PX2”.

The first bit line BL1 may be connected to a source/drain of the first pass transistor PX1. The second bit line BL2 may be connected to a source/drain of the second pass transistor PX2. For example, the first bit line BL1 may be connected to the drain of the first pass transistor PX1, and the second bit line BL2 may be connected to the drain of the second pass transistor PX2.

The word line WL may be connected to a gate of the first pass transistor PX1 and a gate of the second pass transistor PX2. When a word line (WL) signal is applied to the gates of the pass transistors PX1 and PX2, the pass transistors PX1 and PX2 are turned on; in this case, a data bit stored in the memory cell MC is transmitted to a sense amplifier connected to first ends of the bit lines BL1 and BL2, and the sense amplifier amplifies and outputs the signal received through the bit lines BL1 and BL2.

The first inverter may include a first pull-up transistor PU1 and a first pull-down transistor PD1. The second inverter may include a second pull-up transistor PU2 and a second pull-down transistor PD2.

The first and second pull-up transistors PU1 and PU2 may be P-type field effect transistors (PFET), and the first and second pull-up transistors PD1 and PD2 may be N-type field effect transistors (NFET). In some implementations, one pull-up transistor and one pull-down transistor may constitute one inverter.

Sources of the first and second pull-up transistors PU1 and PU2 may be connected to a power line VDD. Sources of the first and second pull-down transistors PD1 and PD2 may be connected to a ground line VSS.

A drain of the first pull-up transistor PU1 and a drain of the first pull-down transistor PD1 may be connected. The source/drain of the first pass transistor PX1 may be connected to the drain of the first pull-up transistor PU1 and the drain of the first pull-down transistor PD1 at a first node N1. For example, the drain of the first pass transistor PX1 may be connected to the drain of the first pull-up transistor PU1 and the drain of the first pull-down transistor PD1 at the first node N1. The first node N1 may be connected to a gate of the second pull-up transistor PU2 and a gate of the second pull-down transistor PD2.

A drain of the second pull-up transistor PU2 and a drain of the second pull-down transistor PD2 may be connected. The source/drain of the second pass transistor PX2 may be connected to the drain of the second pull-up transistor PU2 and the drain of the second pull-down transistor PD2 at a second node N2. For example, the drain of the second pass transistor PX2 may be connected to the drain of the second pull-up transistor PU2 and the drain of the second pull-down transistor PD2 at the second node N2. The second node N2 may be connected to a gate of the first pull-up transistor PU1 and a gate of the first pull-down transistor PD1.

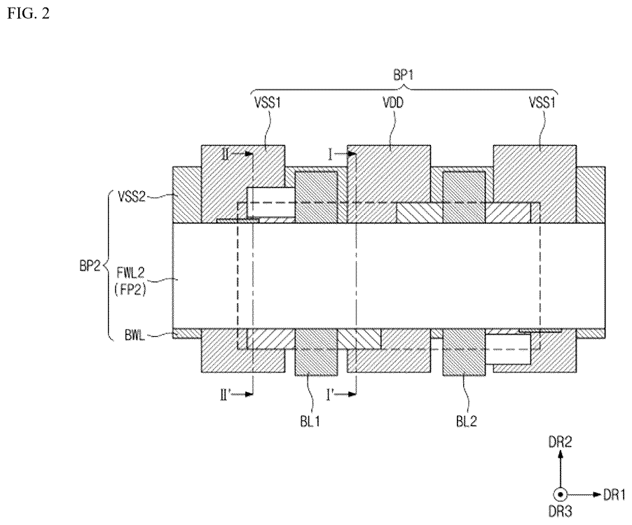

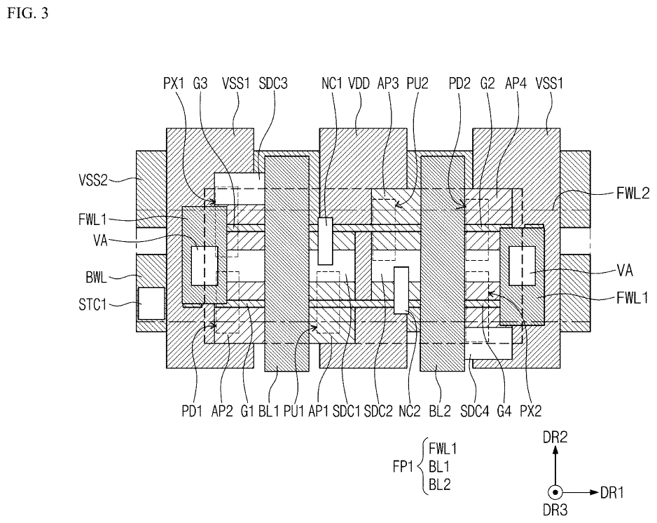

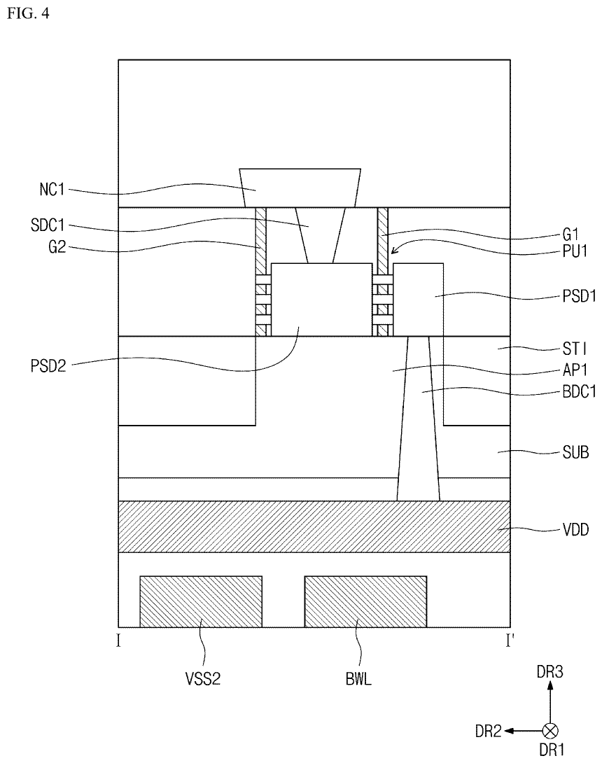

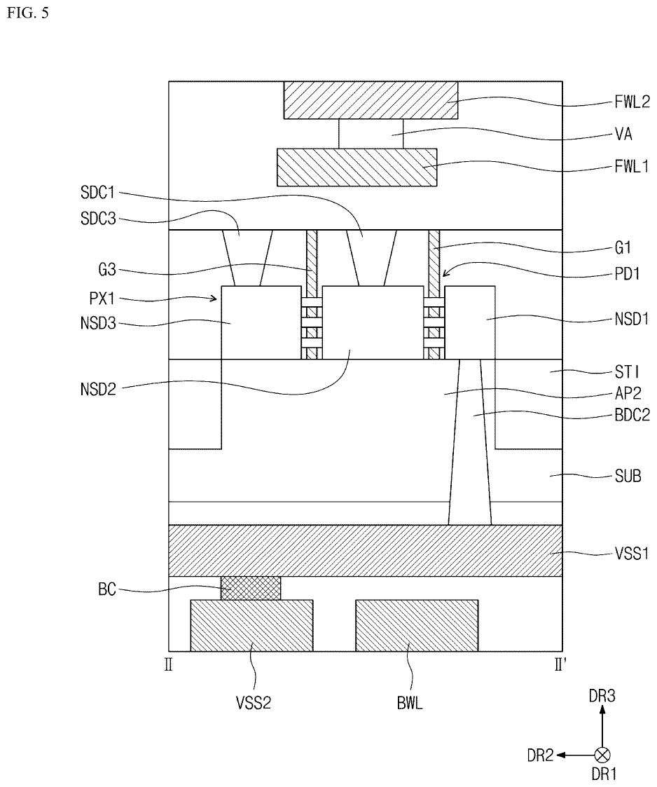

FIG. 2 is a view illustrating a layout of a semiconductor device according to some implementations. FIG. 3 is a view illustrating a layout of a semiconductor device according to some implementations. FIG. 4 is a cross-sectional view taken along line I-I′ of FIG. 2. FIG. 5 is a cross-sectional view taken along line II-II′ of FIG. 2.

Referring to FIGS. 2 to 5, the semiconductor device may include a substrate SUB, transistors on a front surface of the substrate SUB, a first front pattern FP1, a second front pattern FP2, a first back pattern BP1, and a second back pattern BP2. The first front pattern FP1 and the second front pattern FP2 may be on the front surface of the substrate SUB, and the first back pattern BP1 and the second back pattern BP2 may be on the back surface of the substrate SUB.

The substrate SUB may include active patterns defined by a shallow device isolation pattern STI. The shallow device isolation pattern STI may fill a shallow trench formed in the substrate SUB. In detail, the substrate SUB may include a first active pattern AP1, a second active pattern AP2, a third active pattern AP3, and a fourth active pattern AP4 defined by the shallow device isolation pattern STI. The substrate (SUB) may include at least one of silicon, germanium, or silicon-germanium.

The transistors may include the first pull-up transistor PU1 on the first active pattern AP1, the first pull-up transistor PU1 and the first pass transistor PX1 on the second active pattern AP2, the second pull-up transistor PU2 on the third active pattern AP3, and the second pull-down transistor PD2 and the second pass transistor PX2 on the fourth active pattern AP4. The transistors PU1, PU2, PD1, PD2, PX1, and PX2 may be formed on the active patterns AP1 to AP4.

Gate electrodes may be provided on the front surface of the substrate SUB. The gate electrodes may extend in a first direction DR1. The gate electrodes may be arranged to be spaced from each other in a second direction DR2.

In detain, a first gate electrode G1 and a second gate electrode G2 may respectively extend in the first direction DR1 and may be spaced apart from each other in the second direction DR2. The second direction DR2 may intersect the first direction DR1. For example, the second direction DR2 may be orthogonal to the first direction DR1.

In detail, the first gate electrode G1 may be provided on the first active pattern AP1 and the second active pattern AP2. The first gate electrode G1 may extend in the first direction DR1 on the first active pattern AP1 and the second active pattern AP2. In this way, the first pull-up transistor PU1 and the first pull-down transistor PD1 may share the first gate electrode G1.

The second gate electrode G2 may be provided on the third active pattern AP3 and the fourth active pattern AP4. The second gate electrode G2 may extend in the first direction DR1 on the third active pattern AP3 and the fourth active pattern AP4. In this way, the second pull-up transistor PU2 and the second pull-down transistor PD2 may share the second gate electrode G2.

A third gate electrode G3 may be provided on the second active patterns AP2. The third gate electrode G3 may extend in the first direction DR1 on the second active pattern AP2. The first pass transistor PX1 may include the third gate electrode G3. The third gate electrode G3 may be provided next to the second gate electrode G2. That is, the third gate electrode G3 may be disposed in line with the second gate electrode G2. Also, the third gate electrode G3 may be disposed in parallel with the first gate electrode G1.

A fourth gate electrode G4 may be provided on the fourth active pattern AP4. The fourth gate electrode G4 may extend in the first direction DR1 on the fourth active pattern AP4. The second pass transistor PX2 may include the fourth gate electrode G4. The fourth gate electrode G4 may be provided next to the first gate electrode G1. That is, the fourth gate electrode G4 may be disposed in line with the first gate electrode G1. Also, the fourth gate electrode G4 may be disposed in parallel with the second gate electrode G2.

Source/drain contacts may be provided on the front surface of the substrate SUB. The source/drain contacts may extend in the first direction DR1. The source/drain contacts may be arranged in parallel with the gate electrodes.

A first source/drain contact SDC1 may be provided on the first active pattern AP1 and the second active pattern AP2. The first source/drain contact SDC1 may extend in the first direction DR1 on the first active pattern AP1 and the second active pattern AP2. The first source/drain contact SDC1 may be provided between the first gate electrode G1 and the third gate electrode G3. Also, the first source/drain contact SDC1 may be provided between the first gate electrode G1 and the second gate electrode G2.

The first source/drain contact SDC1 may electrically connect the first active pattern AP1 and the second active pattern AP2. For example, the first source/drain contact SDC1 may electrically connect a drain region PSD2 of the first pull-up transistor PU1 on the first active pattern AP1 and a drain region NSD2 of the first pull-down transistor PD1 on the second active pattern AP2.

A second source/drain contact SDC2 may be provided on the third active pattern AP3 and the fourth active pattern AP4. The second source/drain contact SDC2 may extend in the first direction DR1 on the third active pattern AP3 and the fourth active pattern AP4. The second source/drain contact SDC2 may be provided between the second gate electrode G2 and the fourth gate electrode G4. Also, the second source/drain contact SDC2 may be provided between the second gate electrode G2 and the first gate electrode G1. The second source/drain contact SDC2 may be spaced apart from the first source/drain contact SDC1.

The second source/drain contact SDC2 may electrically connect the third active pattern AP3 and the fourth active pattern AP4. For example, the second source/drain contact SDC2 may electrically connect a drain region of the second pull-up transistor PU2 on the third active pattern AP3 and a drain region of the second pull-down transistor PD2 on the fourth active pattern AP4.

A third source/drain contact SDC3 may be provided on the second active patterns AP2. The third source/drain contact SDC3 may extend in the first direction DR1 on the second active pattern AP2. The third gate electrode G3 may be located between the first source/drain contact SDC1 and the third source/drain contact SDC3. The third source/drain contact SDC3 may be electrically connected to the first front pattern FP1 and the first bit line BL1. For example, a drain region NSD3 of the first pass transistor PX1 may be electrically connected to the first bit line BL1 through the third source/drain contact SDC3.

A fourth source/drain contact SDC4 may be provided on the fourth active patterns AP4. The fourth source/drain contact SDC4 may extend in the first direction DR1 on the fourth active pattern AP4. The fourth gate electrode G4 may be interposed between the second source/drain contact SDC2 and the fourth source/drain contact SDC4. The fourth source/drain contact SDC4 may be electrically connected to the first front pattern FP1 and the second bit line BL2. For example, a drain region of the second pass transistor PX2 may be electrically connected to the second bit line BL2 through the fourth source/drain contact SDC4.

The semiconductor device may further include a first node contact NC1 connecting the second gate electrode G2 and the first source/drain contact SDC1. The first node contact NC1 may be provided on the second gate electrode G2 and the first source/drain contact SDC1. The first node contact NC1 may extend in the second direction DR2. The first node contact NC1 and the first source/drain contact SDC1 may form the first node N1 of the equivalent circuit 20.

The semiconductor device may further include a second node contact NC2 connecting the first gate electrode G1 and the second source/drain contact SDC2. The second node contact NC2 may be provided on the first gate electrode G1 and the second source/drain contact SDC2. The second node contact NC2 may extend in the second direction DR2. The second node contact NC2 may be spaced apart from the first node contact NC1 in the first direction DR1. The second node contact NC2 and the second source/drain contact SDC2 may form the second node N2 of the equivalent circuit 20.

The first front pattern FP1 may be provided on the front surface of the substrate SUB. The first front pattern FP1 may include a pair of first front word line FWL1 and a pair of bit lines BL1 and BL2. The pair of bit lines BL1 and BL2 may include the first bit line BL1 and the second bit line BL2. Because the ground lines VSS and the power lines VDD are disposed on the back surface of the substrate SUB, the routing resource in the first front pattern FP1 may be increased. This may mean that the parasitic capacitance of the first front pattern FP1 decreases.

The semiconductor device may further include the second front pattern FP2. The second front pattern FP2 may be provided on a front surface of the first front pattern FP1. The second front pattern FP2 may include second front word lines FWL2. The second front word lines FWL2 may extend in the first direction DR1. The second front word lines FWL2 may be arranged in the second direction DR2. The second front word lines FWL2 may be electrically connected to the first front word line FWL1.

The first back pattern BP1 may be provided on the back surface of the substrate SUB. The first back pattern BP1 may include first ground lines VSS1 and the power lines VDD.

The second back pattern BP2 may be provided on the back surface of the substrate SUB. The second back pattern BP2 may be provided on a back surface of the first back pattern BP1. That is, the first back pattern BP1 may be interposed between the back surface of the substrate SUB and the second back pattern BP2. The second back pattern BP2 may include second ground lines VSS2 and back word lines BWL. The second front word lines FWL2 may vertically overlap the back word lines BWL.

Because the first back pattern BP1 and the second back pattern BP2 are disposed on the back surface of the substrate SUB, the routing resource on the front surface of the substrate SUB may be increased. That is, because the routing resource of the semiconductor device is distributed into the front surface and the back surface of the substrate SUB, the complexity of the routing resource may decrease, and a routing path may be shortened.

Also, a semiconductor device capable of reducing a resistance of a wire and a parasitic capacitance between wires may be provided.

In addition, the dimensions of the semiconductor device may decrease.

Referring to FIG. 4, the first source/drain contact SDC1 may be provided on the drain region PSD2 of the first pull-up transistor PU1. In this way, the first source/drain contact SDC1 may be electrically connected to the drain region PSD2 of the first pull-up transistor PU1.

The first node contact NC1 may be provided on the first source/drain contact SDC1 and may be electrically connected to the first source/drain contact SDC1. Also, the first node contact NC1 may be provided on the second gate electrode G2 and may be electrically connected to the second gate electrode G2.

The semiconductor device may include direct contacts penetrating the substrate SUB. The direct contacts may include a first direct contact BDC1 which connects the power line VDD and a source region PSD1 of the first pull-up transistor PU1. The first direct contact BDC1 may be provided on the front surface of the first back pattern BP1. In detail, the first direct contact BDC1 may be provided on a front surface of the power line VDD. The first direct contact BDC1 may penetrate the back surface of the substrate SUB and may be connected to the source region PSD1 of the first pull-up transistor PU1 on the front surface of the substrate SUB.

According to the above description, the power lines VDD may be directly connected to the pull-up transistors PU1 and PU2 on the substrate SUB through the first direct contact BDC1.

Also, the length for the connection between the power lines VDD and the pull-up transistors PU1 and PU2 may be shortened, which means that the resistance is reduced.

In addition, a semiconductor device capable of making the voltage drop phenomenon better and improving stability may be provided.

Referring to FIG. 5, the first source/drain contact SDC1 may be provided on the drain region NSD2 of the first pull-down transistor PD1. In this way, the first source/drain contact SDC1 may be electrically connected to the drain region NSD2 of the first pull-down transistor PD1.

The third source/drain contact SDC3 may be provided on the source/drain region NSD3 of the first pass transistor PX1. For example, the third source/drain contact SDC3 may be provided on the drain region NSD3 of the first pass transistor PX1. In this way, the third source/drain contact SDC3 may be electrically connected to the drain region NSD3 of the first pass transistor PX1.

The semiconductor device may include a via VA which electrically connects the first front pattern FP1 and the second front pattern FP2. In detail, the via VA may electrically connect the first front word line FWL1 and the second front word lines FWL2. The via VA may be provided on the first front word line FWL1.

The direct contacts may include a second direct contact BDC2 which connects the first ground line VSS1 and a source region NSD1 of the first pull-down transistor PD1. The second direct contact BDC2 may be provided on the front surface of the first back pattern BP1. In detail, the second direct contact BDC2 may be provided on a front surface of the first ground line VSS1. The second direct contact BDC2 may penetrate the back surface of the substrate SUB and may be connected to the source region NSD1 of the first pull-down transistor PD1 on the front surface of the substrate SUB.

According to the above description, the ground lines VSS may be directly connected to the pull-down transistors PD1 and PD2 on the substrate SUB through the second direct contact BDC2.

Also, the length for the connection between the ground lines VSS and the pull-down transistors PD1 and PD2 may be shortened, which means that the resistance is reduced.

In addition, a semiconductor device capable of making the voltage drop phenomenon better and improving stability may be provided.

The semiconductor device may further include a back contact BC provided between the first back pattern BP1 and the second back pattern BP2. In detail, the back contact BC may be provided between the first ground line VSS1 and the second ground line VSS2. In this way, the back contact BC may electrically connect the first ground line VSS1 and the second ground line VSS2.

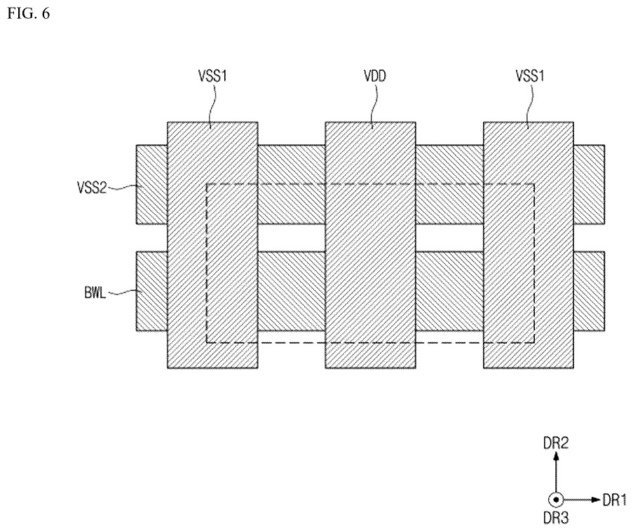

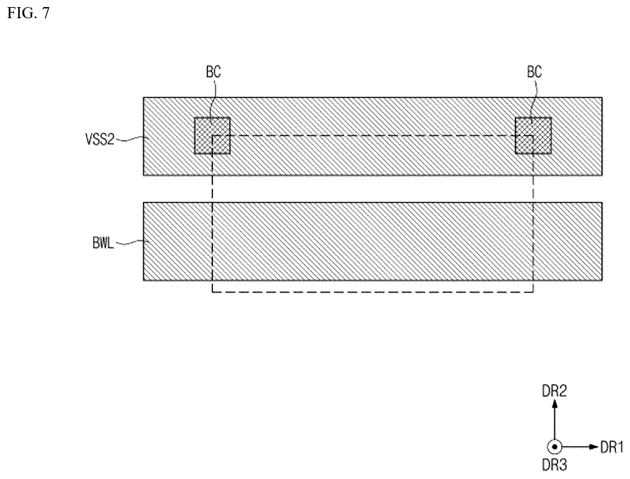

FIG. 6 is a view illustrating a layout of the first back pattern BP1 and the second back pattern BP2 according to some implementations. FIG. 7 is a view illustrating a layout of a layout of the second back pattern BP2 to some implementations.

Referring to FIGS. 6 and 7, the second back pattern BP2 may include the second ground lines VSS2 and the back word lines BWL, which are elongated. For convenience of description, one second ground line VSS2 and one back word line BWL which are provided on a back surface of any one of the memory cells MC are only illustrated in FIGS. 6 and 7. However, it is obvious that the second ground line VSS2 and the back word line BWL are provided in plurality to correspond to the plurality of memory cells MC.

Each of the second ground lines VSS2 may extend in the first direction DR1. The second ground lines VSS2 may be arranged in the second direction DR2. For example, each of the second ground lines VSS2 may overlap a first long side of any one of the memory cells MC.

The back word lines BWL may extend in the first direction DR1. Each of the back word lines BWL may be provided on a back surface of any one of the memory cells MC. That is, each of the back word lines BWL may overlap any one of the memory cells MC. The back word line BWL may cross any one of the memory cells MC. The back word lines BWL may be spaced apart from the second ground lines VSS2 in the second direction DR2.

The back contacts BC may be provided on the second ground lines VSS2. In detail, the back contacts BC may be provided on front surfaces of the second ground lines VSS2. The back contacts BC may overlap corners of any one of the memory cells MC.

The first back pattern BP1 may be provided on a front surface of the second back pattern BP2. In detail, the first ground lines VSS1 may be provided on the back contacts BC. According to the above description, the first ground lines VSS1 may be electrically connected to the second ground lines VSS2 through the back contacts BC.

This may mean that resistances of the ground lines VSS decrease.

In addition, the performance of the semiconductor device may be improved. For example, read performance of a memory cell may be improved.

The first ground lines VSS1 may extend in the second direction DR2. The first ground lines VSS1 may be arranged in the first direction DR1. The first ground lines VSS1 may be spaced apart from each other. Each of the memory cells MC may include a first end and a second end facing away from each other in the first direction DR1, and each of the first ground lines VSS1 may overlap the first ends or the second ends of the memory cells MC arranged in the second direction DR2. For example, each of the first ground lines VSS1 may overlap a first short side or a second short side of any one of the memory cells MC, and the first short side and the second short side may be opposite to each other.

Each of the power lines VDD may be provided between the first ground lines VSS1 adjacent to each other. In detail, the power lines VDD and the first ground lines VSS1 may be arranged alternately in the first direction DR1. Each of the power lines VDD may overlap the memory cells MC arranged in the second direction DR2. Each of the power lines VDD may cross the memory cells MC arranged in the second direction DR2. In detail, each of the power lines VDD may overlap central portions of the memory cells MC arranged in the second direction DR2.

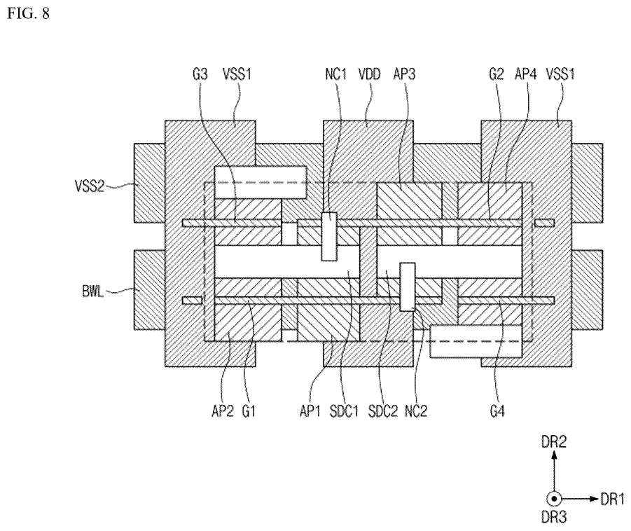

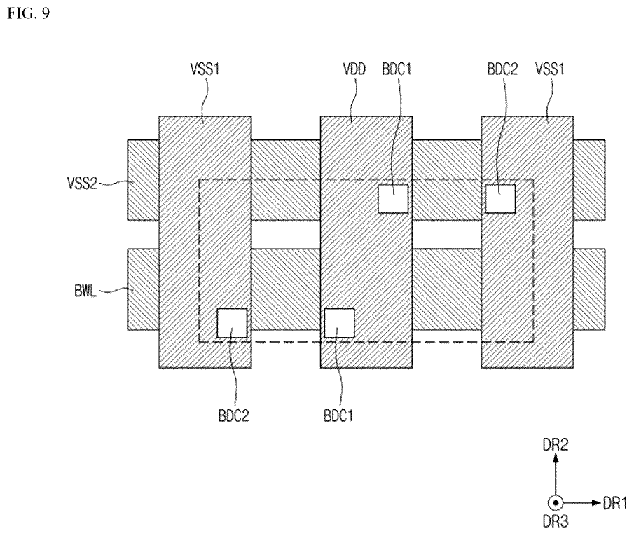

FIG. 8 is a view illustrating a layout of the first back pattern BP1, the second back pattern BP2, and the memory cell MC according to some implementations. FIG. 9 is a view illustrating a layout of the first back pattern BP1 and the second back pattern BP2 according to some implementations.

Referring to FIGS. 2 to 5, 8 and 9, the first direct contacts BDC1 may be provided on the power lines VDD. A pair of first direct contacts BDC1 may be connected to any one of the memory cells MC. In a plan view, one of the pair of first direct contacts BDC1 may overlap the first pull-up transistor PU1, and the other of the pair of first direct contacts BDC1 may overlap the second pull-up transistor PU2. In detail, one of the pair of first direct contacts BDC1 may overlap the source region of the first pull-up transistor PU1, and the other of the pair of first direct contacts BDC1 may overlap the source region of the second pull-up transistor PU2.

The second direct contacts BDC2 may be provided on the first ground lines VSS1. A pair of second direct contacts BDC2 may be connected to any one of the memory cells MC. In a plan view, one of the pair of second direct contacts BDC2 may overlap the first pull-down transistor PD1, and the other of the pair of second direct contacts BDC2 may overlap the second pull-down transistor PD2. In detail, one of the pair of second direct contacts BDC2 may overlap the source region of the first pull-down transistor PD1, and the other of the pair of second direct contacts BDC2 may overlap the source region of the second pull-down transistor.

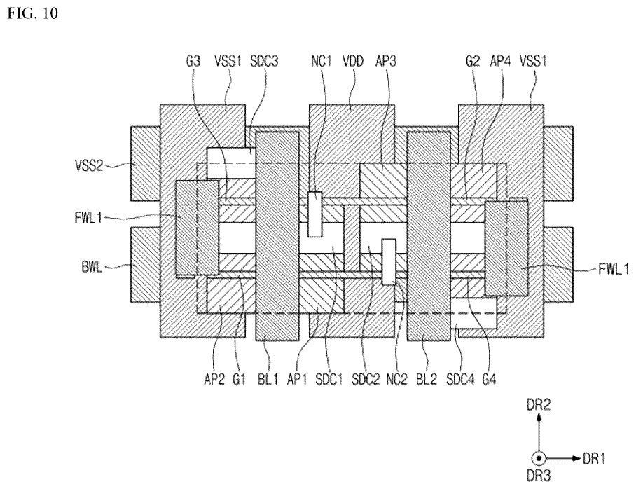

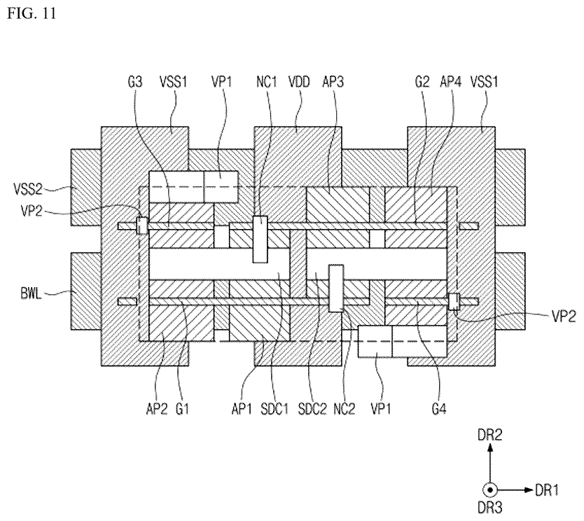

FIG. 10 is a view illustrating a layout of the first back pattern BP1, the second back pattern BP2, the memory cell MC, and the first front pattern FP1 according to some implementations. FIG. 11 is a view illustrating a layout of the first back pattern BP1, the second back pattern BP2, and the memory cell MC according to some implementations.

Referring to FIGS. 10 and 11, the first front pattern FP1 may include the first front word lines FWL1, the first bit lines BL1, and the second bit lines BL2. The first front word lines FWL1 may be arranged in the first direction DR1 and the second direction DR2. The first front word lines FWL1 may extend in the second direction DR2. In detail, the first front word lines FWL1 may overlap one side and an opposite side of any one of the memory cells MC. In detail, a pair of first front word lines FWL1 may overlap a first short side and a second short side of any one of the memory cells MC. The first front word lines FWL1 may vertically overlap the first ground lines VSS1.

The first and second bit lines BL1 and BL2 may extend in the second direction DR2. The first and second bit lines BL1 and BL2 may be arranged alternately in the first direction DR1. The first and second bit lines BL1 and BL2 may cross the memory cells MC arranged in the second direction DR2. One first bit line BL1 and one second bit line BL2 may be provided between the pair of first front word lines FWL1.

The semiconductor device may further include first via patterns VP1 which connect the drain regions of the pass transistors PX1 and PX2 and the bit lines BL1 and BL2. In detail, the first via patterns VP1 may be provided on the drain regions of the first pass transistors PX1 and the drain regions of the second pass transistors PX2. In detail, some of the first via patterns VP1 may be provided on the third source/drain contacts SDC3 which are on the drain regions of the first pass transistors PX1. The others of the first via patterns VP1 may be provided on the fourth source/drain contact SDC4 which are on the drain regions of the second pass transistors PX2.

The first and second bit lines BL1 and BL2 of the first front pattern FP1 may be provided on the first via patterns VP1. In detail, some of the first via patterns VP1 may connect the drain regions of the first pass transistors PX1 and the first bit lines BL1. Also, the others of the first via patterns VP1 may connect the drain regions of the second pass transistors PX2 and the second bit lines BL2.

The semiconductor device may include second via patterns VP2 provided on the gate electrodes of the pass transistors PX1 and PX2. In detail, some of the second via patterns VP2 may be provided on the third gate electrode G3, and the others of the second via patterns VP2 may be provided on the fourth gate electrode G4. According to the above description, the gates of the first and second pass transistors PX1 and PX2 may be electrically connected to the first front word lines FWL1 through the second via patterns VP2.

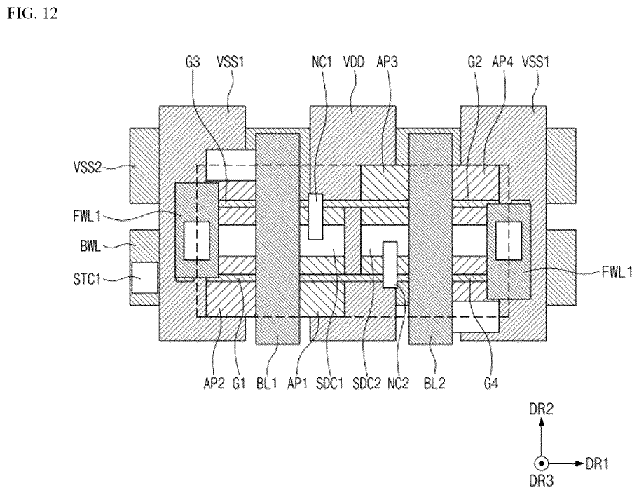

FIG. 12 is a view illustrating a layout of the first back pattern BP1, the second back pattern BP2, the memory cell MC, and the first front pattern FP1 according to some implementations.

Referring to FIG. 12, the semiconductor device may further include first through vias STC1 which electrically connect the back word lines BWL and the second front word lines FWL2. The first through vias STC1 may penetrate the substrate SUB. The second front word lines FWL2 may vertically overlap the back word lines BWL, and the first through vias STC1 may be provided between the second front word lines FWL2 and the back word lines BWL. The first through vias STC1 may vertically overlap the second front word lines FWL2 and the back word lines BWL. The first through vias STC1 may not overlap the memory cells MC. That is, in a plan view, the first through vias STC1 may be located outside the memory cells MC.

In detail, the first through vias STC1 may be provided on end portions of the back word lines BWL. For example, some of the first through vias STC1 may connect first ends of the back word lines BWL and first ends of the second front word lines FWL2, and the others of the first through vias STC1 may connect second ends of the back word lines BWL and second ends of the second front word lines FWL2. According to the above description, finally, the gates of the pass transistors PX1 and PX2 may be electrically connected to the back word lines BWL of the second back pattern BP2.

Accordingly, the back word lines BWL may be disposed on the back surface of the substrate SUB.

The vias VA may be provided on the first front word lines FWL1. The vias VA may be provided between the first front word lines FWL1 and the second front word lines FWL2. In a plan view, the vias VA may overlap the first front word lines FWL1 and the second front word lines FWL2.

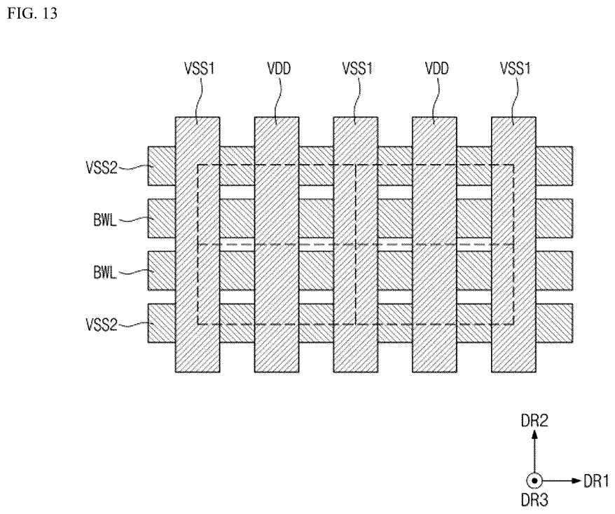

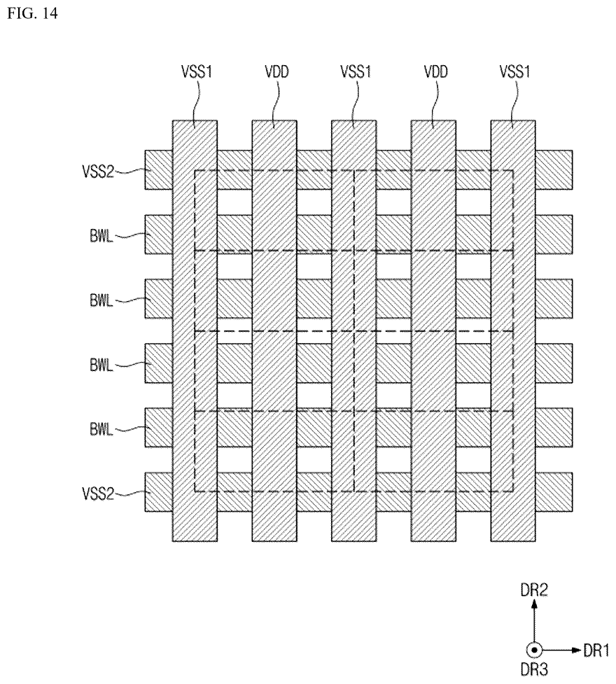

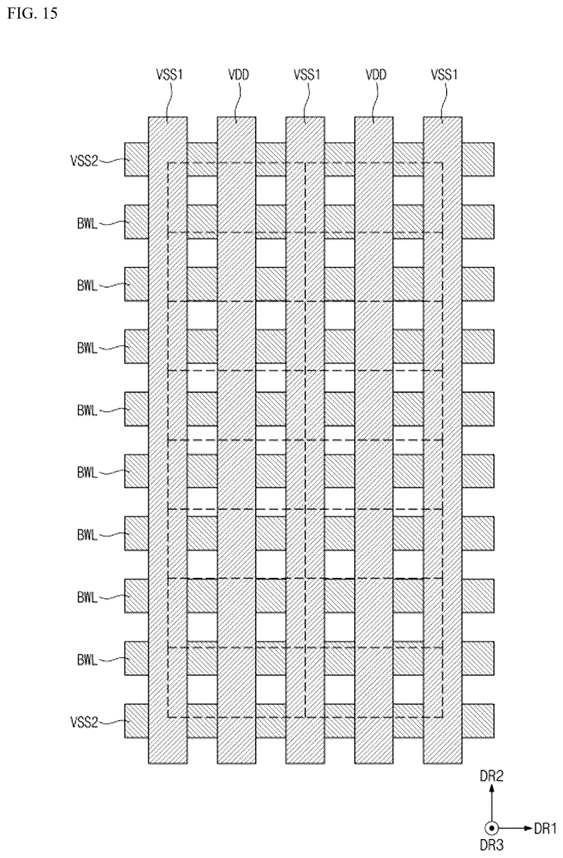

FIG. 13 is a view illustrating a layout of the first back pattern BP1 and the second back pattern BP2 according to some implementations. FIG. 14 is a view illustrating a layout of the first back pattern BP1 and the second back pattern BP2 according to some implementations. FIG. 15 is a view illustrating a layout of the first back pattern BP1 and the second back pattern BP2 according to some implementations.

Referring to FIGS. 13 to 15, the second ground lines VSS2 may be arranged in the second direction DR2. The second ground lines VSS2 may be spaced apart from each other.

Each of the second ground lines VSS2 may be disposed every 2ⁿ memory cells MC arranged in the second direction DR2. Herein, “n” may include “0 ” and an arbitrary natural number. For example, one of the second ground lines VSS2 may overlap the first memory cell MC among the memory cells MC arranged in the second direction DR2, and the others thereof may be arranged one by one every 2ⁿ memory cells MC among the memory cells MC arranged in the second direction DR2.

The back word lines BWL may be provided between the second ground lines VSS2. In detail, the back word lines BWL may be provided between a pair of second ground lines VSS2 adjacent to each other. In more detail, 2ⁿ back word lines BWL may be periodically arranged between a pair of second ground lines VSS2 adjacent to each other. The back word lines BWL may be arranged to be spaced apart from each other in the second direction DR2. For example, the pair of second ground lines VSS2 may be arranged to vertically overlap two memory cells MC arranged in the second direction DR2, respectively, and two back word lines BWL may be provided between the pair of second ground lines VSS2. In this case, the two back word lines BWL may overlap the two memory cells MC arranged in the second direction DR2, respectively.

In some implementations, referring to FIG. 14, the pair of second ground lines VSS2 may be arranged to vertically overlap the outermost memory cells MC among four memory cells MC arranged in the second direction DR2, and four back word lines BWL may be provided between the pair of second ground lines VSS2. In this case, the four back word lines BWL may overlap the four memory cells MC arranged in the second direction DR2, respectively.

In some implementations, referring to FIG. 15, the pair of second ground lines VSS2 may be arranged to vertically overlap the outermost memory cells MC among eight memory cells MC arranged in the second direction DR2, respectively, and eight back word lines BWL may be provided between the pair of second ground lines VSS2. In this case, the eight back word lines BWL may overlap the eight memory cells MC arranged in the second direction DR2, respectively.

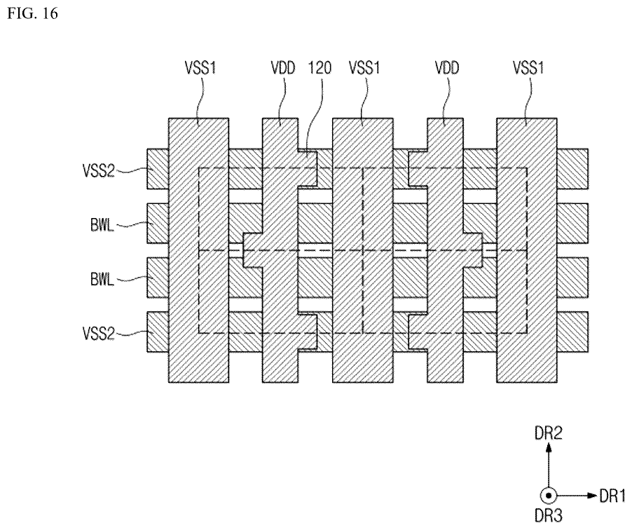

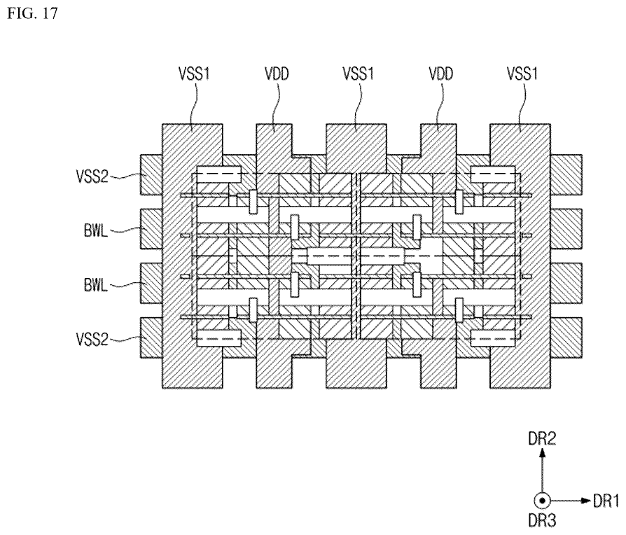

FIG. 16 is a view illustrating a layout of the first back pattern BP1 and the second back pattern BP2 according to some implementations. FIG. 17 is a view illustrating a layout of the first back pattern BP1, the second back pattern BP2, and the memory cells MC according to some implementations.

Referring to FIGS. 16 and 17, each of the power lines VDD may further include a protrusion terminal 120 which overlaps the first pull-up transistor PU1 and/or the second pull-up transistor PU2. The protrusion terminal 120 may extend in a direction parallel to the first direction DR1. For example, the protrusion terminal 120 may extend in the direction parallel to the first direction DR1 and may vertically overlap the source region of the first pull-up transistor PU1 and the source region of the second pull-up transistor PU2.

According to the above description, the distance between the power lines VDD and the pull-up transistors PU1 and PU2 may be shortened.

Also, as the resistance between the power lines VDD and the pull-up transistors PU1 and PU2 decreases, a semiconductor device in which the voltage drop phenomenon is improved may be provided.

In addition, as the width of each of the power lines VDD decreases, spaces between the power lines VDD and the first ground lines VSS1 may be further increased.

Moreover, the parasitic capacitance of the first back pattern BP1 may decrease.

Besides, as the width of each of the power lines VDD decreases, the width of each of the first ground lines VSS1 may increase.

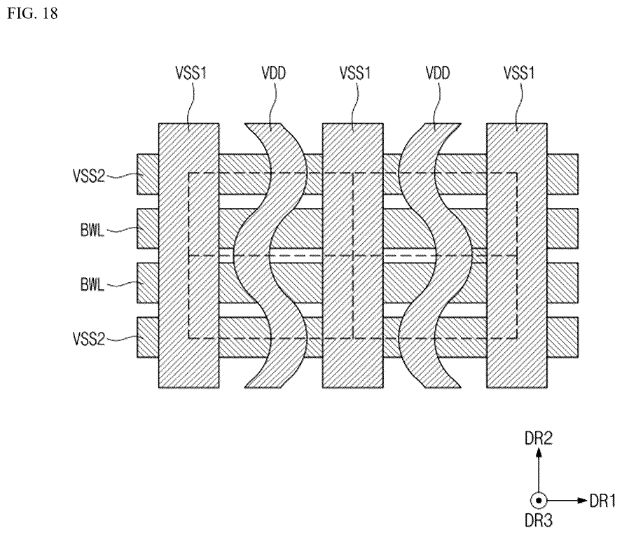

FIG. 18 is a view illustrating a layout of the first back pattern BP1 and the second back pattern BP2 according to some implementations.

Referring to FIG. 18, each of the power lines VDD may be wave-shaped. That is, each of the power lines VDD may extend in the second direction DR2, and may be bent repeatedly in the first direction DR1 and a direction facing away from the first direction DR1, along the extending direction. In this way, each of the power lines VDD may vertically overlap the first pull-up transistor PU1 and the second pull-up transistor PU2. In detail, each of the power lines VDD may vertically overlap the source region of the first pull-up transistor PU1 and the source region of the second pull-up transistor PU2.

According to the above description, the distance between the power lines VDD and the pull-up transistors PU1 and PU2 may be shortened.

Also, as the resistance between the power lines VDD and the pull-up transistors PU1 and PU2 decreases, a semiconductor device in which the voltage drop phenomenon is improved may be provided.

In addition, as the width of each of the power lines VDD decreases, spaces between the power lines VDD and the first ground lines VSS1 may be further increased.

Moreover, the parasitic capacitance of the first back pattern BP1 may decrease.

Besides, as the width of each of the power lines VDD decreases, the width of each of the first ground lines VSS1 may increase.

Accordingly, the distance between the power lines VDD and the source regions of the pull-up transistors PU1 and PU2 may be shortened, and resistances of wires connecting the power lines VDD and the source regions of the pull-up transistors PU1 and PU2 may be reduced.

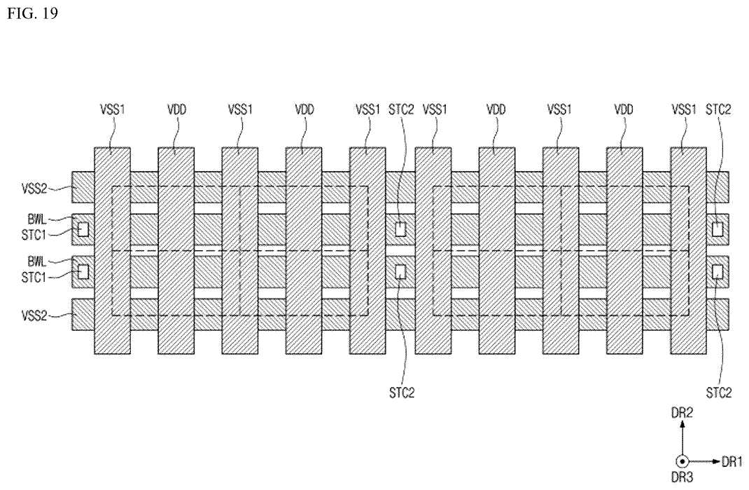

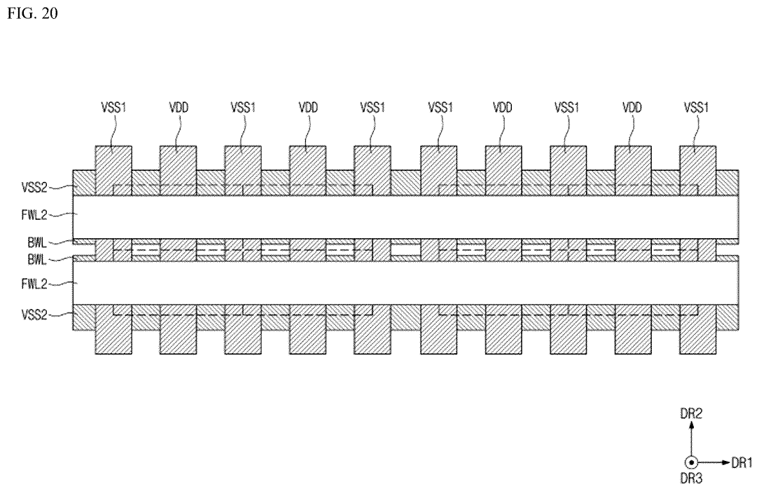

FIG. 19 is a view illustrating a layout of the first back pattern BP1, the second back pattern BP2, and the memory cells MC according to some implementations. FIG. 20 is a view illustrating a layout of the first back pattern BP1, the second back pattern BP2, the memory cells MC, and the second front pattern FP2 according to some implementations.

Referring to FIGS. 19 and 20, the semiconductor device may further include second through vias STC2 provided on the back word lines BWL. The second through vias STC2 may penetrate the substrate SUB. In a plan view, the second through vias STC2 may be provided between the memory cells MC. Some of the memory cells MC arranged in the first direction DR1 may be spaced apart from the others of the memory cells MC in the first direction DR1, and separation spaces may be defined between the some of the memory cells MC and the others of the memory cells MC. The second through vias STC2 may penetrate the substrate SUB so as to be provided in the separation spaces.

The second through vias STC2 may connect the back word lines BWL and the second front word lines FWL2. The second through vias STC2 may be provided on central portions of the back word lines BWL. The second through vias STC2 may be arranged in the first direction DR1 between the first through vias STC1 provided at the end portions of the back word lines BWL.

In a semiconductor device according to implementations of the present disclosure, a routing resource of an integrated circuit may be increased, and a parasitic capacitance of a wire may be decreased. Accordingly, the stability of a voltage supply or the stability of a signal transfer may be improved.

Also, in a semiconductor device according to implementations of the present disclosure, an electrical characteristic may be improved.

Effects obtained from implementations of the present disclosure are not limited to the above effects, and other effects not mentioned may be clearly derived and understood by one skilled in the art to which the implementations of the present disclosure belong from the following description.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A semiconductor device comprising:
a plurality of memory cells on a front surface of a substrate;
a first back pattern on a back surface of the substrate; and
a second back pattern on the back surface of the substrate,
wherein the first back pattern comprises:
a plurality of first ground lines arranged in a first direction and extending in a second direction intersecting the first direction; and
a plurality of power lines extending in the second direction,
wherein the plurality of first ground lines and the plurality of power lines are arranged alternately in the first direction, and
wherein the second back pattern comprises a plurality of back word lines arranged in the second direction and extending in the first direction.

2. The semiconductor device of claim 1, wherein the first back pattern is between the back surface of the substrate and the second back pattern.

3. The semiconductor device of claim 1, wherein the second back pattern further comprises:
a plurality of second ground lines arranged in the second direction and extending in the first direction, and
wherein the plurality of back word lines are between two adjacent second ground lines of the plurality of second ground lines.

4. The semiconductor device of claim 1, wherein each of the plurality of power lines overlaps a central portion of the plurality of memory cells arranged in the second direction from among the memory cells,
wherein each of the plurality of memory cells comprises a first end and a second end facing away from each other in the first direction, and
wherein each of the plurality of first ground lines overlaps the first ends or the second ends of the memory cells arranged in the second direction.

5. The semiconductor device of claim 1, wherein each of the plurality of memory cells comprises:
a first pull-up transistor and a first pull-down transistor that share a first gate electrode extending in the first direction; and
a second pull-up transistor and a second pull-down transistor that share a second gate electrode, and
wherein the second gate electrode extends in the first direction and is spaced apart from the first gate electrode in the second direction.

6. The semiconductor device of claim 5, wherein each of the plurality of power lines comprises a protrusion terminal overlapping the first pull-up transistor and the second pull-up transistor.

7. The semiconductor device of claim 5, wherein each of the plurality of power lines is wave-shaped and overlaps the first pull-up transistor and the second pull-up transistor.

8. The semiconductor device of claim 5, further comprising:
a plurality of first direct contacts extending into a plurality of source regions of the first and second pull-up transistors and connected to the plurality of power lines,
wherein each of the plurality of memory cells is connected to the plurality of power lines.

9. The semiconductor device of claim 5, further comprising:
a plurality of second direct contacts extending into source regions of the first and second pull-down transistors and connected to the plurality of first ground lines,
wherein each of the memory cells is electrically connected to the plurality of first ground lines.

10. The semiconductor device of claim 1, further comprising:
a first front pattern on the front surface of the substrate,
wherein the first front pattern comprises:
a plurality of first front word lines arranged in the first direction and extending in the second direction; and
a first bit line and a second bit line extending in the second direction and between two adjacent first front word lines of the plurality of first front word lines.

11. The semiconductor device of claim 10, wherein the plurality of first front word lines vertically overlap the plurality of first ground lines.

12. The semiconductor device of claim 10, further comprising:
a second front pattern on the first front pattern,
wherein the second front pattern comprises a plurality of second front word lines arranged in the second direction and extending in the first direction, and
wherein the plurality of second front word lines vertically overlap the plurality of back word lines.

13. The semiconductor device of claim 12, further comprising:
a plurality of first through vias connecting first ends of the plurality of second front word lines and first ends of the plurality of back word lines and connecting second ends of the plurality of second front word lines and second ends of the plurality of back word lines.

14. The semiconductor device of claim 13, wherein a subset of memory cells of the plurality of memory cells are arranged in the first direction,
wherein first memory cells of the subset of memory cells are spaced apart from second memory cells of the subset of memory cells, and
wherein the semiconductor device comprises:
a plurality of second through vias between the first memory cells and the second memory cells, and connecting the plurality of second front word lines and the plurality of back word lines.

15. The semiconductor device of claim 1, wherein each of the plurality of memory cells comprises a static random memory cell.

16. A semiconductor device comprising:
a plurality of memory cells on a front surface of a substrate;
a first back pattern on a back surface of the substrate; and
a second back pattern on the back surface of the substrate,
wherein the first back pattern comprises a plurality of first ground lines arranged in a first direction and extending in a second direction intersecting the first direction,
wherein the second back pattern comprises a plurality of second ground lines arranged in the second direction and extending in the first direction, and
wherein the plurality of second ground lines are connected to the plurality of first ground lines.

17. The semiconductor device of claim 16, wherein each of the plurality of second ground lines between every 2ⁿ memory cells of the plurality of memory cells that are arranged in the second direction, the n being a natural number.

18. The semiconductor device of claim 16, wherein the second back pattern further comprises a plurality of back word lines arranged in the second direction and extending in the first direction, and
wherein 2ⁿ back word lines of the plurality of back word lines are between two adjacent second ground lines of the plurality of second ground lines, the n being a natural number.

19. A semiconductor device comprising:
a plurality of memory cells on a substrate;
a signal back pattern on a back surface of the substrate;
a first front pattern on a front surface of the substrate;
a second front pattern on a front surface of the first front pattern; and
a plurality of first word via lines connecting the signal back pattern and the second front pattern,
wherein the signal back pattern comprises a plurality of back word lines extending in a first direction and arranged in a second direction intersecting the first direction,
wherein the first front pattern comprises a plurality of first front word lines arranged in the first direction and extending in the second direction,
wherein the second front pattern comprises a plurality of second front word lines extending in the first direction and vertically overlapping the plurality of back word lines,
wherein the plurality of second front word lines are connected to the plurality of first front word lines, and
wherein the plurality of first word via lines connect first ends of the plurality of second front word lines and first ends of the plurality of back word lines and connect second ends of the plurality of second front word lines and second ends of the plurality of the back word lines.

20. The semiconductor device of claim 19, wherein a subset of memory cells of the plurality of memory cells are arranged in the first direction,
wherein first memory cells of the subset of memory cells are spaced apart from second memory cells of the subset of memory cells, and
wherein the semiconductor device comprises:
a plurality of second through vias between the first memory cells and the second memory cells, and connecting the plurality of second front word lines and the plurality of back word lines.
